(19) United States
(12) Patent Application Publication
(10) Pub. No.: US 2005/0074700 A1
(43) Pub. Date: Apr. 7, 2005

(54) Method for imaging a semiconductor wafer

(75) Inventors: Francis Lin, Hsinchu (TW); Mars Yang, Hsinchu (TW); W. P. Lu, Hsinchu (TW); Vincent Chen, Hsinchu (TW); C. Y. Chin, Hsinchu (TW); Paul Chen, Hsinchu (TW)

Correspondence Address: OSTROLENK FABER GERB & SOFFEN, 1180 AVENUE OF THE AMERICAS, NEW YORK, NY, 100368403, US

(73) Assignee: Macronix International Co., Ltd.

(21) Appl. No.: 10/680,311

(22) Filed: Oct. 7, 2003

(51) Int. Cl. G03F 7/00; G03F 7/20

(52) U.S. Cl. 430/313; 430/394; 430/396

(57) ABSTRACT

A method for imaging a semiconductor wafer includes the steps of preparing a mask that is formed with at least first and second mask patterns, positioning the mask on an exposure system, positioning the wafer on the exposure system, forming a first image, which corresponds to the first mask pattern, on the wafer, removing the wafer from the exposure system, subjecting the wafer to subsequent integrated circuit forming steps, repositioning the wafer on the exposure system, and forming a second image, which corresponds to the second mask pattern, on the wafer.

### BACKGROUND OF THE INVENTION

1. Field of the Invention

This invention relates to a method for imaging a semiconductor wafer during formation of an integrated circuit on the semiconductor wafer.

2. Description of the Related Art

An integrated circuit product is formed by defining patterns in various layers on a semiconductor wafer. Conventionally, formation of each of the aforesaid layers requires a corresponding mask for each photolithography processing step. Each mask is mounted on an exposure system, such as a proximity-type exposure system, a contact-type exposure system, or a stepper apparatus, and is required to be properly aligned during the corresponding photolithography processing step.

FIG. 1 illustrates a conventional mask 1 that is formed with six spaced apart identical mask patterns 11, four coarse alignment marks 12 at corners thereof, and four fine alignment marks 14. Two adjacent ones of the mask patterns 11 are separated by an opaque chrome film 13 that has a thickness of about several hundreds A to prevent interference between the two adjacent mask patterns 11 during an exposing operation. FIG. 2 is a block diagram illustrating consecutive steps of a method for forming an integrated circuit on a semiconductor wafer. The method includes the steps of: (a) preparing a mask that is formed with a plurality of identical maskpatterns; (b) positioning the maskon anexposure system; (c) positioning the wafer on the exposure system; (d) forming images, which respectively correspond to the mask patterns, on the wafer by projecting light through the mask onto the wafer; (e) removing the wafer from the exposure system; (f) subjecting the wafer to subsequent integrated circuit forming steps so as to form a layer of the integrated circuit on the semiconductor wafer; (g) positioning another mask, which is formed with identical mask patterns that are different from the previous mask patterns, on the exposure system; (h) repositioning the wafer on the exposure system; (i) forming images (each image is defined hereinafter as a latent on a photoresist layer on the wafer), which respectively correspond to the mask patterns of said another mask, on the wafer by projecting light through said another mask onto the wafer; (j) subjecting the wafer to further integrated circuit forming steps so as to form another layer of the integrated circuit on the layer of the integrated circuit previuosly formed on the wafer; and (k) repeating the steps from (g) to (j) so as to form all of the layers of the integrated circuit on the wafer.

It is known in the art that mask positioning contributes to main alignment error of the wafer in relation to the exposure system, which can result in a considerably large overlay error (i.e., the difference between the desired position and the actual position of the mask image on the wafer), which, in turn, has an adverse effect on the production yield of the integrated circuit products. As a consequence, the accumulated overlay error will be larger, and the integration of integrated circuit products will be poorer as more masks are used. In addition, since the cost for each mask is relatively expensive, and since a relatively large quantity of masks is normally used for developing a prototype product, the cost of the masks can be a substantial portion of the total manufacturing cost for producing low volume quantities of wafer products or prototype wafers.

### SUMMARY OF THE INVENTION

Therefore, the object of the present invention is to provide a method for imaging a semiconductor wafer that is capable of overcoming the aforesaid drawbacks.

According to the present invention, there is provided a method for imaging a semiconductor wafer during formation of an integrated circuit on the semiconductor wafer. The method comprises the steps of: preparing a mask that is formed with at least first and second mask patterns thereon for forming the integrated circuit on the semiconductor wafer; positioning the mask on an exposure system; positioning the wafer on the exposure system; forming a first image, which corresponds to the first mask pattern, on the wafer by projecting light through the mask onto the wafer; removing the wafer from the exposure system; subjecting the wafer to subsequent integrated circuit forming steps; repositioning the wafer on the exposure system; and forming a second image, which corresponds to the second mask pattern, on the wafer by projecting light through the mask onto the wafer.

### BRIEF DESCRIPTION OF THE DRAWINGS

In drawings which illustrate an embodiment of the invention,

FIG. 1 is a schematic view illustrating a conventional mask for photolithography processing;

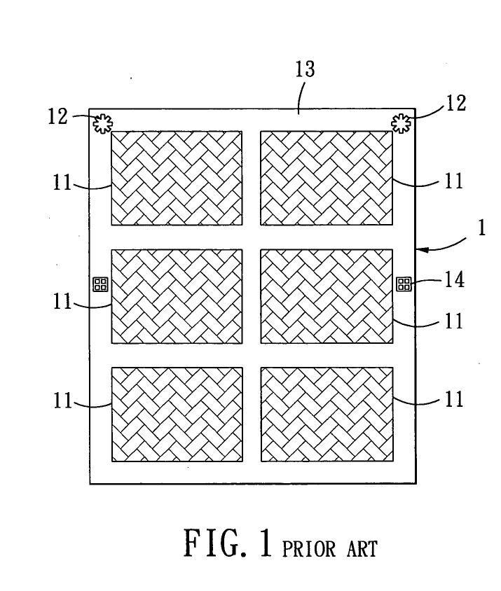

FIG. 2 is a block diagram to illustrate consecutive steps of a conventional method for forming an integrated circuit on the wafer;

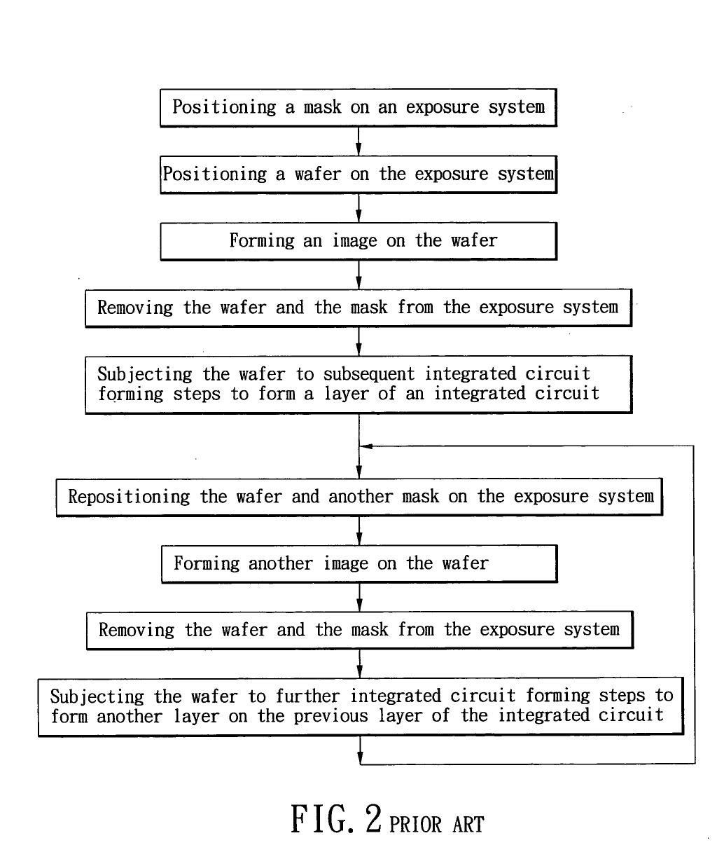

FIG. 3 is a schematic view illustrating a mask for photolithography processing step according to the preferred embodiment of an imaging method of this invention; and

FIG. 4 is a block diagram to illustrate consecutive steps of the preferred embodiment of the method of this invention.

### DETAILED DESCRIPTION OF THE PREFERRED EMBODIMENT

This invention relates to a method for imaging a semiconductor wafer during formation of an integrated circuit on the semiconductor wafer. The method includes the steps of: preparing a mask that is formed with at least first and second mask patterns thereon for forming the integrated circuit on the semiconductor wafer; positioning the mask on an exposure system; positioning the wafer on the exposure system; forming a first image, which corresponds to the first mask pattern, on the wafer by projecting light through the mask onto the wafer; removing the wafer from the exposure system; subjecting the wafer to subsequent integrated circuit forming steps; repositioning the wafer on the exposure system; and forming a second image, which corresponds to the second mask pattern, on the wafer by projecting light through the mask onto the wafer.

The present invention will be described in more detail with reference to the following preferred embodiment.

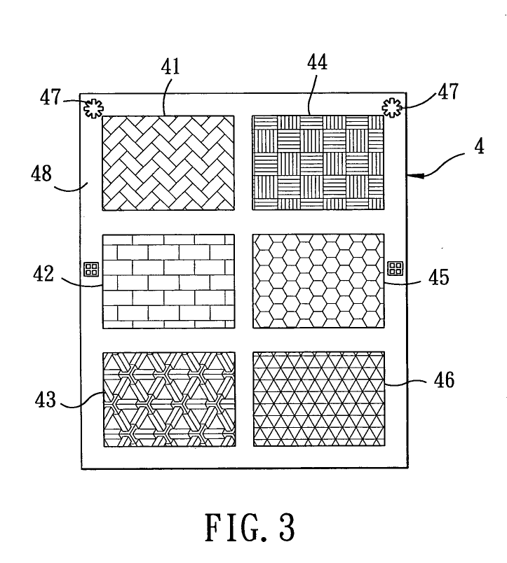

FIG. 3 illustrates a mask 4 for photolithography processing step according to the method of this invention. The mask 4 employed in the method of this invention can be a binary mask or a phase shift mask, and is formed with six different mask patterns 41, 42, 43, 44, 45, 46, and a plurality of alignment marks 47 at corners thereof. Two adjacent ones of the mask patterns 41, 42, 43, 44, 45, 46 are separated by an opaque chrome film 48 that has a thickness of about several hundred A.

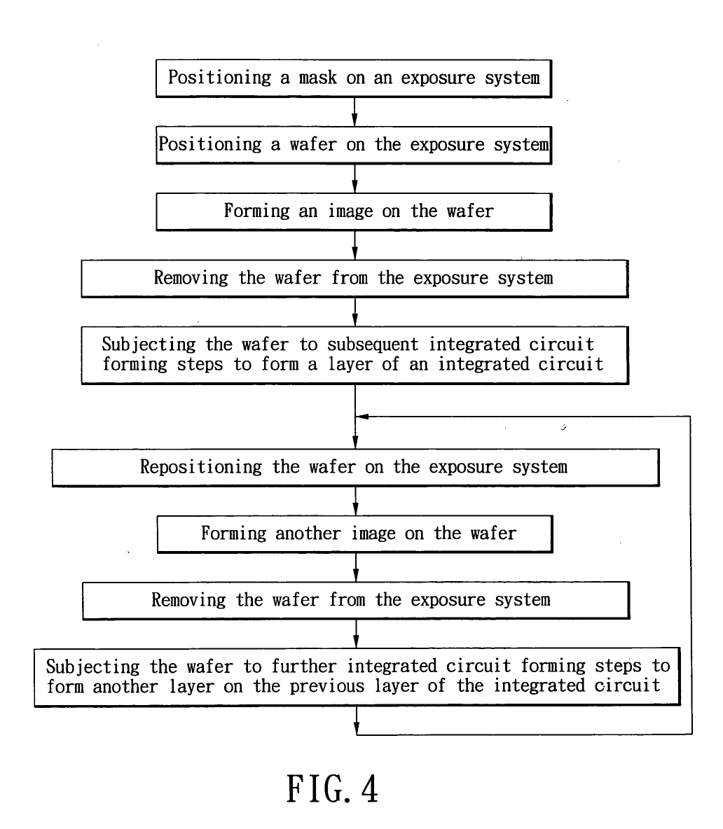

FIG. 4 is a block diagram to illustrate consecutive steps of the method of the first preferred embodiment of this invention for forming a six layer-integrated circuit on the semiconductor wafer using the mask 4 shown in FIG. 3. Each layer of the integrated circuit corresponds to a respective one of the mask patterns 41, 42, 43, 44, 45, 46.

The method of the first embodiment includes the steps of: (a) preparing the aforesaid mask 4; (b) positioning the mask 4 on an exposure system, such as a proximity-type exposure system, a contact-type exposure system, or a step-and-repeat stepper apparatus, by aligning the alignment marks 47 with a set of reference marks provided by the exposure system; (c) positioning the wafer on the exposure system by aligning alignment marks on the wafer with another set of reference marks provided by the exposure system; (d) forming an image, which corresponds to the mask pattern 41, on the wafer by projecting light through the mask 4 onto the wafer (note that the image is actually formed on a photoresist layer on the wafer, and that a photoresist layer is also required to be applied to the wafer before the wafer can be patterned) ; (e) removing the wafer from the exposure system; (f) subjecting the wafer to subsequent integrated circuit forming steps so as to form the respective layer of the integrated circuit on the semiconductor wafer; (g) repositioning the wafer on the exposure system; (h) forming another image, which corresponds to the mask pattern 42, on the wafer by projecting light through the mask onto the wafer; (i) removing the wafer from the exposure system; (j) subjecting the wafer to further integrated circuit forming steps so as to form the respective layer of the integrated circuit on the layer of the integrated circuit previously formed on the wafer; and (i) repeating the steps from (g) to (j) so as to form other layers of the integrated circuit that respectively correspond to the mask patterns 43, 44, 45, 46. The aforesaid integrated circuit forming steps include at least one of photoresist developing, photoresist baking, photoresist removing or etching, and depositing and or doping.

Table 1 shows the overlay error data in X and Y directions for an Example 1 of the first preferred embodiment and a Comparative Example 1 which also used six masks for forming the corresponding six layers of the integrated circuit on the wafer.

TABLE 1

| | Example 1 | | Comparative Example 1 | |
|---|---|---|---|---|
| Layer of the | Overlay | Overlay | Overlay | Overlay |
| integrated | error in | error in | error in | error in |
| circuit | X-direction, | Y-direction, | X-direction, | Y-direction, |
| on the wafer | nm | nm | nm | nm |
| Second layer | 12 | 31 | 53 | 42 |
| Fourth layer | 25 | 10 | 43 | 28 |

Since the mask 4 is aligned only once throughout the formation of the layers of the integrated circuit as compared to that of the comparative Example which requires six mask alignments, the overlay error (see Table 1) of the integrated circuit product made according to this invention is significantly reduced as compared to that of the prior art. Moreover, since only a single mask with the requisite mask patterns for forming the various layers of the integrated circuit on the wafer is employed in the method of this invention (six masks are required for the Comparative Example), the manufacturing cost for the production of small quantities of wafer products or prototype wafers can be considerably reduced.

The method of this invention can be also applied to form a complicated structured layer of an integrated circuit on the wafer or to enhance production yield of the integrated circuit on the wafer. In such cases, at least two mask patterns are required to be formed on the mask for the formation of a desired layer of the integrated circuit. For example, a portion of a layer of the integrated circuit can be formed on the wafer using one of the mask patterns on the mask, whereas another portion of the layer of the integrated circuit can be subsequently formed on the wafer using another one of the mask patterns on the mask. Through the method of this invention, different functions of dies can be easily and cost effectively formed on a wafer.

The method of this invention is particularly suitable for producing low volume quantities of wafer product or prototype wafers.

With the invention thus explained, it is apparent that various modifications and variations can be made without departing from the spirit of the present invention. It is therefore intended that the invention be limited only as recited in the appended claims.

1. A method for imaging a semiconductor wafer during formation of an integrated circuit on the semiconductor wafer, the method comprising the steps of:
preparing a mask that is formed with at least first and second mask patterns thereon for forming the integrated circuit on the semiconductor wafer;
positioning the mask on an exposure system;
positioning the wafer on the exposure system;
forming a first image, which corresponds to the first mask pattern, on the wafer by projecting light through the mask onto the wafer;
removing the wafer from the exposure system;
subjecting the wafer to subsequent integrated circuit forming steps;
repositioning the wafer on the exposure system; and
forming a second image, which corresponds to the second mask pattern, on the wafer by projecting light through the mask onto the wafer.

2. A method for forming an integrated circuit on a semiconductor wafer, the method comprising the steps of:
(a) preparing a mask that is formed with a plurality of mask patterns thereon for forming the integrated circuit on the semiconductor wafer;
(b) positioning the mask on an exposure system;
(c) positioning the wafer on the exposure system;
(d) forming an image, which corresponds to one of the mask patterns, on the wafer by projecting light through the mask onto the wafer;
(e) removing the wafer from the exposure system;
(f) subjecting the wafer to subsequent integrated circuit forming steps so as to form a layer of the integrated circuit on the semiconductor wafer;
(g) repositioning the wafer on the exposure system;
(h) forming another image, which corresponds to another one of the mask patterns, on the wafer by projecting light through the mask onto the wafer;
(i) removing the wafer from the exposure system;
(j) subjecting the wafer to further integrated circuit forming steps so as to form another layer of the integrated circuit on the layer of the integrated circuit previously formed on the wafer; and
(i) repeating the steps from (g) to (j) so as to form other layers of the integrated circuit on the wafer.

3. The method of claim 2, wherein the integrated circuit forming steps include at least one of photoresist developing, photoresist baking, photoresist removing or etching, and depositing and or doping.

4. The method of claim 3, wherein the mask is a binary mask.

5. The method of claim 3, wherein the mask is a phase shift mask.

6. A method for forming an integrated circuit on a semiconductor wafer, the method comprising the steps of:
(a) preparing a mask that is formed with a plurality of mask patterns thereon for forming the integrated circuit on the semiconductor wafer;
(b) positioning the mask on an exposure system;
(c) positioning the wafer on the exposure system;
(d) forming an image, which corresponds to one of the mask patterns, on the wafer by projecting light through the mask onto the wafer;
(e) removing the wafer from the exposure system;
(f) subjecting the wafer to subsequent integrated circuit forming steps so as to form a portion of a layer of the integrated circuit on the semiconductor wafer;
(g) repositioning the wafer on the exposure system;
(h) forming another image, which corresponds to another one of the mask patterns, on the wafer by projecting light through the mask onto the wafer;
(i) removing the wafer from the exposure system; and
(j) subjecting the wafer to integrated circuit forming steps so as to form another portion of the layer of the integrated circuit.
